(19) United States
(12) Patent Application Publication
(10) Pub. No.: US 2014/0227072 A1
(43) Pub. Date: Aug. 14, 2014

(54) WAFER TRANSFER BLADE AND WAFER TRANSFER APPARATUS HAVING THE SAME

(71) Applicant: Samsung Electronics Co., Ltd., Suwon-Si (KR)

(72) Inventors: Dong-Yoon LEE, Yongin-si (KR); Jun-Young MUN, Suwon-si (KR); Dong-Il PARK, Hwaseong-si (KR); Suk-Yong JUNG, Hwaseong-si (KR); Bo-Young HWANG, Suwon-si (KR)

(73) Assignee: Samsung Electronics Co., Ltd., Suwon-Si (KR)

(21) Appl. No.: 14/178,392

(22) Filed: Feb. 12, 2014

(30) Foreign Application Priority Data
Feb. 14, 2013 (KR) 10-2013-0015605

(51) Int. Cl. H01L 21/683; B25J 15/00; B25J 15/06

(52) U.S. Cl. CPC H01L 21/6838; B25J 15/0616; B25J 15/0019
USPC 414/744.3; 294/183; 294/188; 294/213

(57) ABSTRACT

A wafer transfer blade including a body including metal oxide and configured to support a wafer, and an adsorbing part on the body, the adsorbing part having at least one therein and configured to apply vacuum pressure to attach the wafer on the body may be provided. The body may include metal oxide to prevent static electricity.

### CROSS-REFERENCE TO RELATED APPLICATION

This application claims priority under 35 USC §119 to Korean Patent Application No. 10-2013-0015605, filed on Feb. 14, 2013 in the Korean Intellectual Property Office (KIPO), the contents of which are herein incorporated by reference in their entirety.

### BACKGROUND

1. Field

Example embodiments relate to a wafer transfer blade and/or a wafer transfer apparatus having the wafer transfer blade. More particularly, example embodiments relate a wafer transfer blade for manufacturing a semiconductor and/or a wafer transfer apparatus having the wafer transfer blade.

2. Description of the Related Art

Generally, a wafer transfer apparatus includes a wafer transfer blade. During a manufacturing process of a wafer, the wafer may be loaded to or un-loaded from a front opening unified pod (FOUP) using the wafer transfer blade. At this time, static electricity generated during the manufacturing process may interrupt the wafer being separated from the wafer transfer blade while the wafer is loaded or un-loaded, thereby causing, for example, the wafer to be shocked in the FOUP of the wafer transfer apparatus.

### SUMMARY

At least one example embodiment provides a wafer transfer blade capable of decreasing a shock during a wafer loading/unloading process.

At least one example embodiment provides a wafer transfer apparatus having the wafer transfer blade.

According to some example embodiments, a wafer transfer blade may include a body configured to support a wafer. The body may include metal oxide and at least one a vacuum hole defined therein. The first vacuum hole may be configured to apply vacuum pressure therethrough such that the wafer is attached to the body.

In some example embodiments, the metal oxide may be titanium dioxide.

In some example embodiments, the wafer transfer blade may further include a first branch extending from the body, and a second branch extending from the body. The first branch may include at least one second vacuum hole defined therein, the second branch may include at least one third vacuum hole defined therein, and the first to third vacuum holes may be configured to apply vacuum pressures therethrough such that the wafer is attached to the body

In some example embodiments, the body, the first branch and the second branch may form a Y-shape. The first to third vacuum holes may be disposed in a triangle.

In some example embodiments, the body, the first branch and the second branch may be configured to contact the wafer when the wafer is carried thereon.

In some example embodiments, the wafer transfer blade may further include a first contact pad, a second contact pad, and a third contact pad. The first contact pad may be disposed on the body and have a first opening. The second contact pad may be disposed on the first branch and have a second opening. The third contact pad may be disposed on the second branch and have a third opening. The first to third vacuum holes may be connected to the first to third openings of the first to third contact pads, respectively. The first to third contact pads may be configured to contact the wafer such that the body, the first branch, and the second branch may be spaced apart from the wafer when the wafer is carried on the wafer transfer blade.

In some example embodiments, the first to third contact pads may include polyimide plastic.

In some example embodiments, the wafer transfer blade may further include a ground part connected to the body to discharge static electricity.

According to some example embodiments, a wafer transfer blade may include a body including metal oxide and configured to support a wafer, a first guide wall formed at a first end of the body, and a second guide wall formed at a second end of the body. The second end may be opposite to the first end.

In some example embodiments, the metal oxide may include titanium dioxide.

In some example embodiments, the body may be configured to contact the wafer when the wafer is carried.

In some example embodiments, the wafer transfer blade may further include a plurality of contact pad disposed on the body. When the wafer is carried on the wafer transfer blade in contact with the contact pads, the wafer may be spaced apart from the body.

According to some example embodiments, a wafer transfer apparatus may include a wafer transfer blade and a first arm connected to the wafer transfer blade. The wafer transfer blade may include a body to support a wafer, and an absorbing part on the body and having at least one vacuum hole therein to apply vacuum pressure to attach the wafer on the body. The body may include metal oxide to prevent static electricity.

In some example embodiments, the metal oxide may include titanium dioxide.

In some example embodiments, the wafer transfer apparatus may further include a second arm connected to the first arm. The wafer transfer blade may be configured to move up and down and right and left based on movements of the first arm and the second arm.

According to some example embodiments, a wafer transfer blade including a metal oxide, which has a relatively low electrical insulation resistance, may transfer a wafer undergone implant process and ashing process with mitigating or preventing static elasticity on the wafer.

According to some example embodiments, a wafer transfer blade may include a body configured to support a wafer and the body may include metal oxide and a wafer holding portion nit configured to hold the wafer.

In some example embodiments, the wafer holding portion may include at least one vacuum hole defined in the body, the vacuum hole configured to apply vacuum pressure therethrough such that the wafer is adsorped to the body.

In some example embodiments, the wafer holding portion may include at least one elastic contact pad.

In some example embodiments, the elastic contact pad may include an opening defined therein, the wafer holding portion may include at least one vacuum hole, and the vacuum hole may be connected to the opening and may be configured to provide vacuum pressure through the opening such that the wafer is adsorped on the elastic contact pad.

In some example embodiments, the wafer holding portion may be defined by at least one guide wall at at least one end of the body, the guide wall configured to confine the wafer within the wafer holding portion. Further, the wafer transfer blade may include first to third vacuum holes formed on a body, a first branch and a second branch, respectively, so that damage to the wafer is prevented or mitigated.

Further, the wafer transfer blade may include first to third contact pads including an elastic material so that damage to the wafer may be prevented or mitigated.

Further, the wafer transfer blade may be separated from the wafer in a direction perpendicular to a lower surface of the wafer during an un-loading in a FOUP so that damage to the wafer may be prevented or mitigated.

### BRIEF DESCRIPTION OF THE DRAWINGS

Example embodiments will be more clearly understood from the following detailed description taken in conjunction with the accompanying drawings. FIGS. 1 to 8B represent non-limiting, example embodiments as described herein.

FIG. 1 is a perspective view illustrating a wafer transfer blade according to an example embodiment.

FIG. 2 is a cross-sectional view illustrating a wafer transfer blade according to an example embodiment;

FIG. 3 is a cross-sectional view taken along line I-I′ of FIG. 2 to explain a process of loading a wafer on the wafer transfer blade;

FIG. 4 is a perspective view illustrating a wafer transfer blade according to another example embodiment;

FIG. 5 is a perspective view illustrating a wafer transfer blade according to still another example embodiment;

FIG. 6 is a cross-sectional view taken along line II-II′ of FIG. 5 to explain a process of loading a wafer on the wafer transfer blade;

FIG. 7 is a perspective view illustrating a wafer transfer blade according to an example embodiment; and

FIGS. 8A and 8B are cross-sectional views briefly illustrating loading and un-loading of a wafer in a wafer receiving container.

### DESCRIPTION OF EXAMPLE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, some example embodiments will be explained in detail with reference to the accompanying drawings.

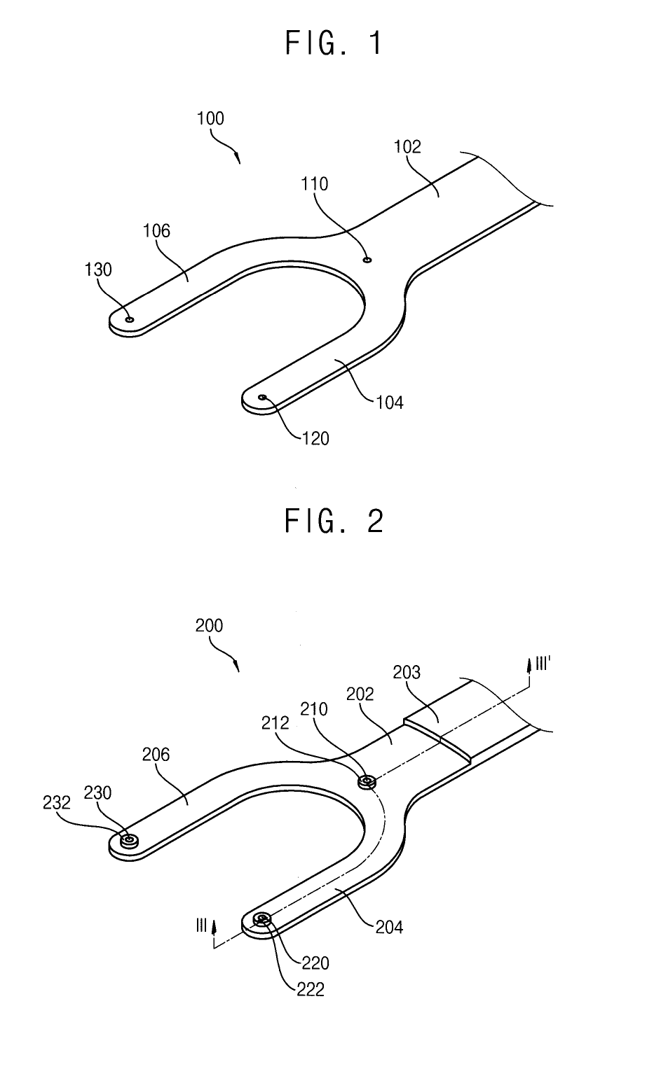

FIG. 1 is a perspective view illustrating a wafer transfer blade according to an example embodiment.

Referring to FIG. 1, a wafer transfer blade 100 may include a body 102, a first branch 104 extending from the body 102, and a second branch 106 extending from the body 102. The wafer transfer blade 100 may have a Y-shape.

The body 102, the first branch 104, and the second branch 106 may include a material which protects the wafer from being damaged by static electricity. For example, the body 102, the first branch 104, and the second branch 106 may include a material (e.g., metal oxide) having a relatively low electrical insulation resistance. For example, the body 102, the first branch 104, and the second branch 106 may include titanium dioxide, which has an electrical insulation resistance of about 1Ω. Further, surfaces of the body 102, the first branch 104, and the second branch 106 may be coated by, e.g., titanium dioxide. In addition, the body 102, body 102, the first branch 104 and the second branch 106 may include ceramic.

When the body 102, the first branch 104, and the second branch 106 are formed using titanium dioxide, during a transferring process of a wafer (e.g., transferring wafer from an implant processing area to an ashing processing area), the wafer transfer blade 100 in the example embodiment experiences static electricity of about 0.1 kv/in on average compared to the average static electricity of about 6 kv/in of a traditional wafer transfer blade. The above result has been confirmed by an experiment.

First to third vacuum holes 110, 120, and 130 may be formed on the wafer transfer blade 100. The first to third vacuum holes 110, 120, and 130 may attach the wafer to the wafer transfer blade 100 using a vacuum pressure. The first to third vacuum holes 110, 120, and 130 may be disposed at positions on the wafer transfer blade 100 to properly carry the wafer. For example, the first vacuum hole 110 may be disposed on the body 102, the second vacuum hole 120 may be disposed on the first branch 104, and the third vacuum hole 130 may be disposed on the second branch 106. Thus, the first to third vacuum holes 110, 120, and 130 may be disposed, for example, in a triangle such that the wafer on the wafer transfer blade 100 is attached and carried by the vacuum pressure with a center of the triangle coinciding with the center of the wafer. At this time, a lower surface of the wafer makes contact with the body 102, the first branch 104, and the second branch 106 of the wafer transfer blade 100.

The first to third vacuum holes 110, 120, and 130 may generate same or similar vacuum pressure such that the first to third vacuum holes 110, 120, and 130 apply the same or similar force to the wafer.

Although not shown in figures, the wafer transfer blade 100 may further include a ground part, which is electrically connected with the body 102 to discharge static electricity.

FIG. 2 is a cross-sectional view illustrating a wafer transfer blade according to an example embodiment.

Referring to FIG. 2, a wafer transfer blade 200 is the same as or similar to the wafer transfer blade 100 of FIG. 1, except for a guide wall 203, first to third contact pads 212, 222, and 232. Thus, detailed descriptions concerning the same or similar elements will be briefly mentioned or omitted.

The wafer transfer blade 200 may include a body 202, a first branch 204 extending from the body 202, and a second branch 206 extending from the body 202.

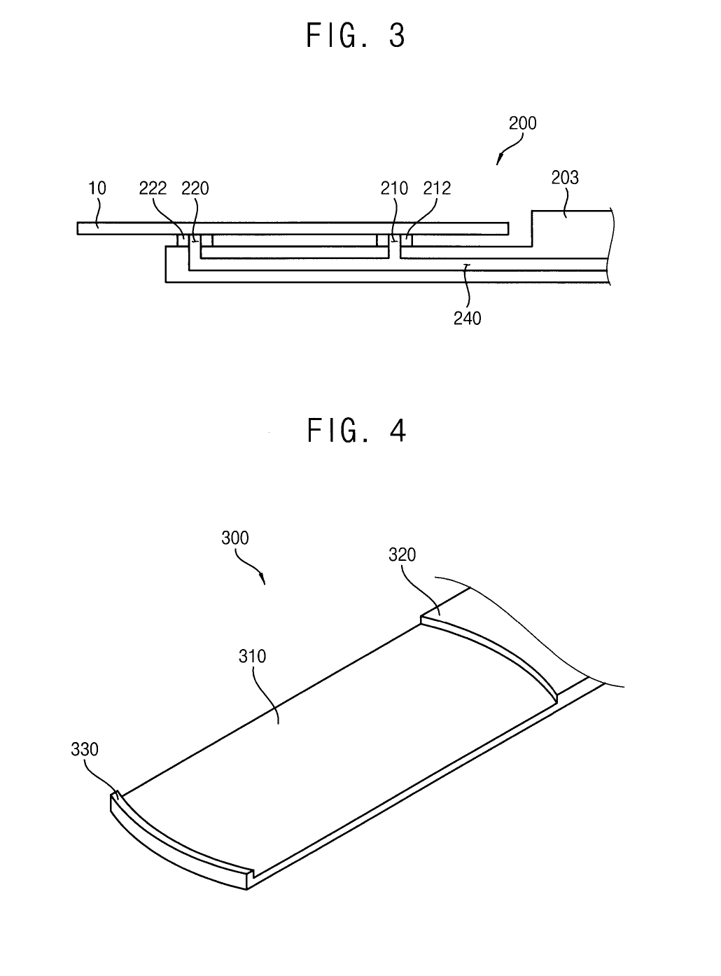

The first to third contact pads 212, 222, and 232 may be disposed on the wafer transfer blade 200. The first contact pad 212 may be disposed on the body 202, the second contact pad 222 may be disposed on the first branch 204, and the third contact pad 232 may be disposed on the second branch 206. The first to third contact pads 212, 222, and 232 may contact a wafer (refers 10 of FIG. 3) to be placed thereon. The first to third contact pads 212, 222, and 232 may have a specific thickness such that the body 202, the first branch 204, and the second branch 206 are separated from the wafer by a desired (or, alternatively predetermined) distance.

The first to third contact pads 212, 222, and 232, which contact the wafer, may include an elastic material to reduce or prevent damage to the wafer. Thus, the first to third contact pads 212, 222 and 232 may include, for example, polyimide plastic (e.g., Vespel sold by Dupont).

The guide wall 203 may be formed on the body 202. The guide wall 203 may have a height greater than a thickness of the first to third contact pads 212, 222 and 232, so that the guide wall 203 may prevent the wafer from being separated or from sliding from the wafer transfer blade 200.

FIG. 3 is a cross-sectional view taken along line I-I′ of FIG. 2 to explain a process of loading a wafer on the wafer transfer blade.

Referring to FIGS. 2 and 3, when a wafer 10 is disposed on the wafer transfer blade 200 (or, alternatively the wafer transfer blade 200 is disposed under the wafer 10), the first to third contact pads 212, 222, and 232 may contact the wafer 10. The first to third contact pads 212, 222, and 232 may have a desired (or, alternatively predetermined) thickness such that the body 202, the first branch 204, and the second branch 206 are spaced apart from the wafer 10. First to third vacuum holes 210, 220, and 230 may be formed at the first to third contact pads 212, 222, and 232, respectively. The first to third vacuum holes 210, 220 and 230 may be connected to a vacuum path 240. The vacuum path 240 may be connected to a vacuum generator (not shown). The vacuum generator may generate vacuum pressure for the wafer transfer blade 2200 to adsorp the wafer 10. At this time, the first to third contact pads 212, 222, and 232 may be formed by an elastic material to prevent or reduce damage to the wafer 10. The first to third contact pads 212, 222, and 232 may include polyimide plastic. The body 202, the first branch 204 and the second branch 206 may include titanium dioxide. Thus, static electricity to be formed on the wafer 10 may be prevented or reduced.

FIG. 4 is a perspective view illustrating a wafer transfer blade according to another example embodiment.

Referring to FIG. 4, a wafer transfer blade 300 may include a body 310, a first guide wall 320, and a second guide wall 320. The first guide wall 320 and the second guide wall 320 may have heights greater than that of the body 310. Thus, the first guide wall 320 and the second guide wall may prevent or minimize a wafer from being separated or from sliding from the wafer transfer blade 300.

When the wafer is carried or placed onto the wafer transfer blade 300 (or, alternatively the wafer blade 300 is placed under the wafer), the wafer may be disposed on the body 310 and may contact the body 310.

The body 310 may include a material which protects the wafer from being damaged by static electricity. The body 310 may include a material (e.g., metal oxide) having a relatively low electrical insulation resistance. For example, the body 302 may include titanium dioxide. Further, surfaces of the body 302 may be coated by, e.g., titanium dioxide. Further, the body 302 may include ceramic.

The wafer transfer blade 300 may not include an additional grip element. Further, the wafer transfer blade 300 may further include an additional grip element (not shown) to prevent the wafer from being separated or from sliding from the wafer transfer blade 300.

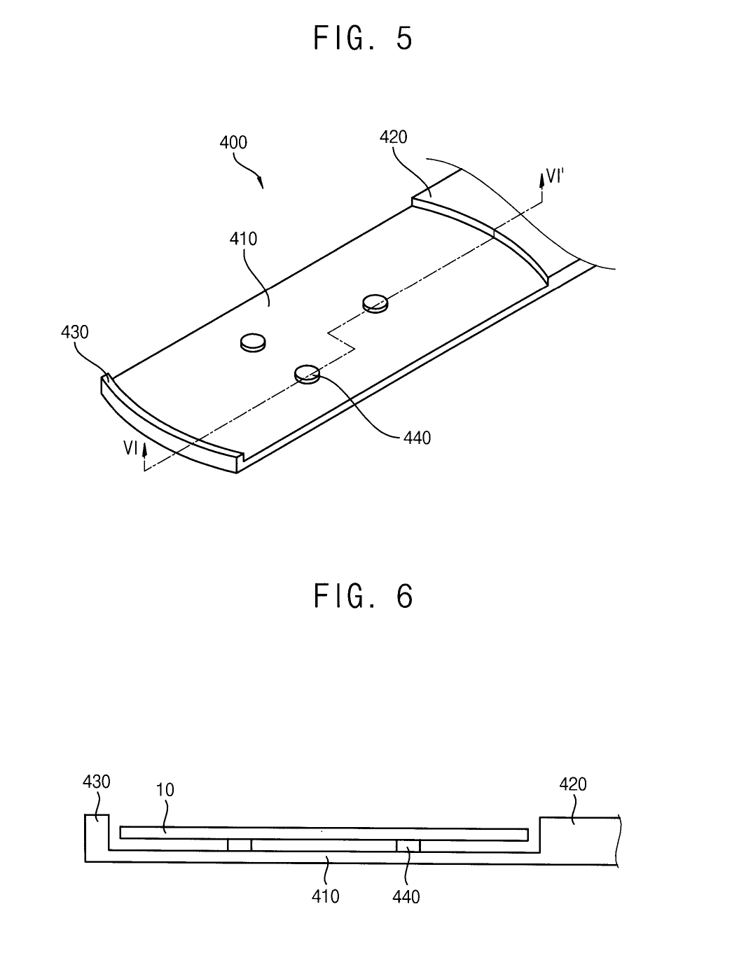

FIG. 5 is a perspective view illustrating a wafer transfer blade according to still another example embodiment.

Referring to FIG. 5, a wafer transfer blade 400 may be substantially same as or similar to the wafer transfer blade 300 of FIG. 4, except for a plurality of contact pads 440. Thus, detailed descriptions concerning the same or similar elements will be briefly mentioned or omitted.

The contact pads 440 may be disposed on a body 410. The contact pads 440 may be disposed, for instance, in a triangle. The contact pads 440 may have a specific height smaller than those of first and second guide walls 420 and 430. Accordingly, A wafer may be prevented from being spaced apart or from sliding from the body 410.

The contact pads 440 may include an elastic material to reduce or prevent damage to the wafer. Thus, the contact pads 440 may include, for example, polyimide plastic (e.g., Vespel sold by Dupont).

FIG. 6 is a cross-sectional view taken along line II-II′ of FIG. 5 to explain a process of loading a wafer on the wafer transfer blade.

Referring to FIGS. 5 and 6, when the wafer 10 is disposed on the wafer transfer blade 400 (or, alternatively the wafer transfer blade 400 is disposed under the wafer 10), the contact pads 440 may contact the wafer 10. The contact pads 440 may have a desired (or, alternatively predetermined) height such that the body 410 is spaced apart from the wafer 10. The wafer transfer blade 400 may include the first and second guide walls 420 and 430. The first and second guide wall 420 and 430may prevent or minimize the wafer 10 disposed on the body 410 from being separated or from sliding from the body 410. At this time, the contact pads 440 may include an elastic material so that damage to the wafer 10 by the contact pads 440 can be prevented or mitigated. The contact pads 440 may include, for example, polyimide plastic, and the body 410 may include, for example, titanium dioxide. Thus, static electricity formed on the wafer 10 may be prevented or reduced.

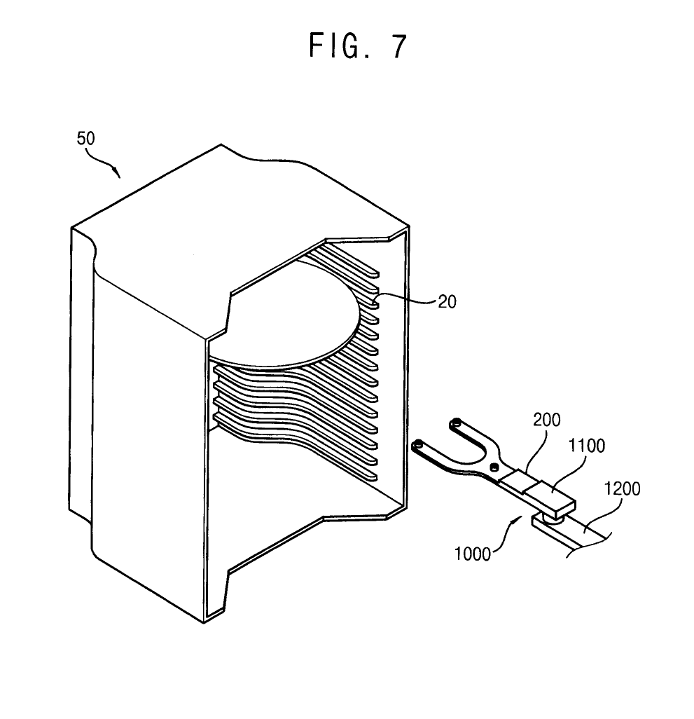

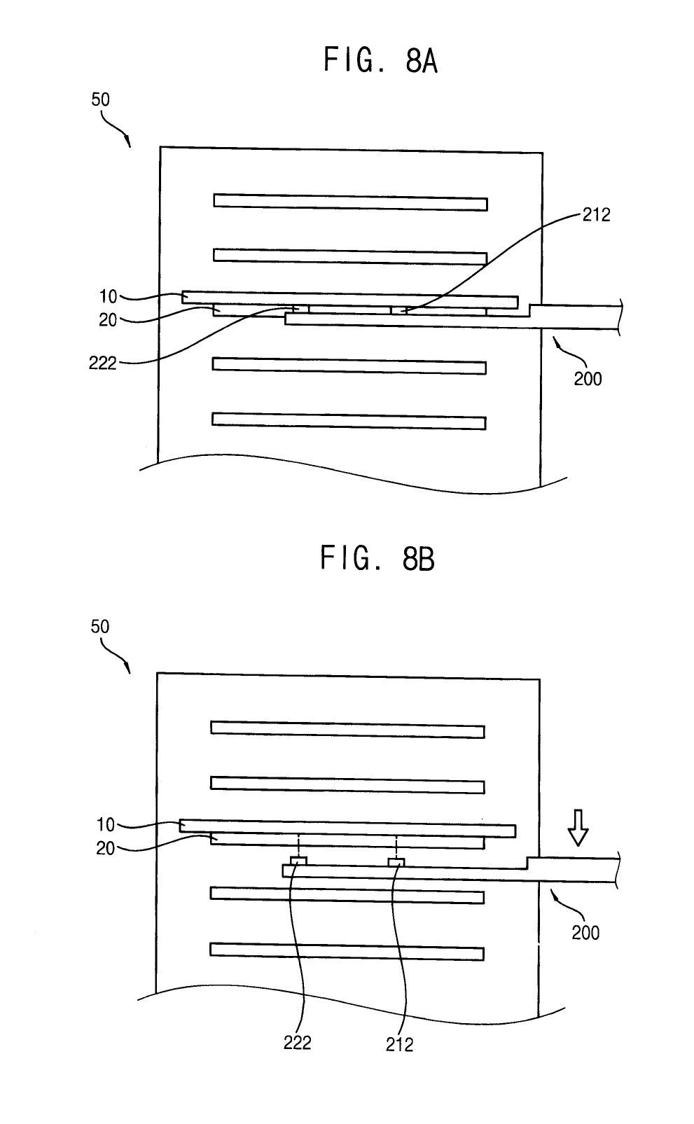

FIG. 7 is a perspective view illustrating a wafer transfer blade according to yet another example embodiment. FIGS. 8A and 8B are cross-sectional views briefly illustrating loading and un-loading of a wafer in a wafer receiving container.

Referring to FIGS. 7 to 8B, a wafer transfer apparatus 1000 may include a wafer transfer blade 200, a first arm 1100 connected to the wafer transfer blade 200, and a second arm 1200 connected to the first arm 1100. The wafer transfer blade 200 may be the same as or similar to a wafer transfer blade of FIG. 2. The first arm 1100 and the second arm 1200 may move respectively to each other such that the wafer transfer blade 200 moves, for example, up and down, and right and left.

An example of loading a wafer 10 in a front opening unified Pod (FOUP) 50 using the wafer transfer apparatus 1000 is described in FIG. 8A. The FOUP 50 may have a plurality of slots 20, each of which may support different wafers 10 therein. A wafer 10 may be received in the FOUP 50 and may be supported by a slot 20. The wafer 10 may be loaded by moving the wafer transfer blade 200 of the wafer transferring apparatus 100 from under the wafer 10, which is in the FOUP 50, to the wafer along a direction perpendicular to a lower surface of the wafer 10. At this time, the wafer 10 may be adsorpted or attached to the wafer transfer blade 200 using vacuum pressure mentioned in FIG. 2.

The wafer transfer blade 200 may include, for example, titanium dioxide, and the first to third contact pads 212, 222, and 232 of FIG. 2 may include, for example, polyimide plastic to reduce or prevent static electricity from being generated on the wafer 10.

An example of un-loading or releasing a wafer 10 in the FOUP 50 using the wafer transfer apparatus 1000 is described in FIG. 8B. The wafer 10 may be disposed on the slot 20 using the wafer transfer blade 200 of the wafer transfer apparatus 1000. By removing the vacuum pressure and moving the wafer transfer blade 200 in a direction perpendicular to the lower surface of the wafer 10, (e.g., in a downward direction away from the wafer 10), the wafer 10 may be un-loaded in the FOUP 50.

The wafer transfer blade 200 may include, for example, titanium dioxide, and the first to third contact pads 212, 222, and 232 of FIG. 2 may include, for example, polyimide plastic to reduce or prevent static electricity from being generated on the wafer 10. Accordingly, generation of static electricity during the un-loading process may be reduced or prevented. Thus, the wafer 10 may not stick or adhere to the wafer transfer blade 200 during the un-loading. As a result, damage to the wafer 10 by the slot 20, which occurs when the wafer 10 adheres to the wafer transfer blade 10, may be decreased or prevented.

According to example embodiments, a wafer transfer blade may include a material (e.g., metal oxide) having a relatively low electrical insulation resistance. Thus, a wafer moving for example, from IMP processing area to an ashing processing area may be carried preventing or reducing static elasticity related problems.

Further, the wafer transfer blade may include first to third vacuum holes formed on a body, a first branch and a second branch, respectively so that damage to the wafer is prevented or minimized.

Further, the wafer transfer blade may include first to third contact pads including, for example, an elastic material so that damage to the wafer is prevented or minimized.

Further, the wafer transfer blade may be separated from the wafer in a direction perpendicular to a lower surface of the wafer during an un-loading in a FOUP such that damage to the wafer is prevented or minimized.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A wafer transfer blade comprising:
a body configured to support a wafer, the body including metal oxide and at least one first vacuum hole defined therein, and the first vacuum hole configured to apply vacuum pressure therethrough such that the wafer is attached to the body.

2. The wafer transfer blade of claim 1, wherein the metal oxide includes titanium dioxide.

3. The wafer transfer blade of claim 2, further comprising;
a first branch extending from the body; and
a second branch extending form the body,
wherein the first branch includes at least one second vacuum hole defined therein, the second branch includes at least one third vacuum hole defined therein, and the first to third vacuum holes configured to apply vacuum pressures therethrough such that the wafer is attached to the body.

4. The wafer transfer blade of claim 3, wherein the body, the first branch, and the second branch form a Y-shape, and the first to third vacuum holes are disposed in a triangle.

5. The wafer transfer blade of claim 4, wherein the body, the first branch, and the second branch are configured to contact the wafer when the wafer is carried thereon.

6. The wafer transfer blade of claim 5, further comprising:
a first contact pad on the body, the first contact pad having a first opening;
a second contact pad on the first branch, the second contact pad having a second opening; and
a third contact pad on the second branch, the third contact pad having a third opening, wherein
the first to third vacuum holes are connected to the first to third openings of the first to third contact pads, respectively, and
the first to third contact pads are configured to contact the wafer such that the body, the first branch, and the second branch are spaced apart from the wafer when the wafer is carried on the wafer transfer blade.

7. The wafer transfer blade of claim 6, wherein the first to third contact pads include polyimide plastic.

8. The wafer transfer blade of claim 6, further comprising:
a ground part connected to the body.

9. A wafer transfer blade comprising:
a body configured to support a wafer, the body including metal oxide;
a first guide wall at a first end of the body; and
a second guide wall at a second end of the body, the second end being opposite to the first end.

10. The wafer transfer blade of claim 9, wherein the metal oxide includes titanium dioxide.

11. The wafer transfer blade of claim 10, wherein the body is configured to contact the wafer when the wafer is carried thereon.

12. The wafer transfer blade of claim 10, further comprising:
a plurality of contact pads on the body,
wherein when the wafer is carried on the wafer transfer blade in contact with the contact pads, the wafer is spaced apart from the body.

13. A wafer transfer apparatus comprising:
the wafer transfer blade of claim 1; and
a first arm connected to the wafer transfer blade.

14. The wafer transfer apparatus of claim 13, wherein the metal oxide includes titanium dioxide.

15. The wafer transfer apparatus of claim 13, further comprising:
a second arm connected to the first arm,
wherein the wafer transfer blade configured to move up and down and right and left based on movements of the first arm and the second arm.

16. A wafer transfer blade comprising:
a body configured to support a wafer, the body including metal oxide and including a wafer holding portion configured to hold the wafer.

17. The wafer transfer blade of claim 16, wherein the wafer holding portion includes at least one vacuum hole defined in the body, the vacuum hole configured to apply vacuum pressure therethrough.

18. The wafer transfer blade of claim 16, wherein the wafer holding portion includes at least one elastic contact pad.

19. The wafer transfer blade of claim 18, wherein the elastic contact pad includes an opening defined therein, the wafer holding portion includes at least one vacuum hole, and the vacuum hole is connected to the opening and is configured to provide vacuum pressure through the opening.

20. The wafer transfer blade of claim 16, wherein the wafer holding portion is defined by at least one guide wall at at least one end of the body, the guide wall configured to confine the wafer within the wafer holding portion.
